(19) United States
(12) Patent Application Publication
(10) Pub. No.: US 2025/0248135 A1
(43) Pub. Date: Jul. 31, 2025

(54) 3T TANDEM SOLAR CELL, TANDEM SOLAR CELL MODULE, AND METHOD FOR PRODUCING SAME

(71) Applicant: HELMHOLTZ-ZENTRUM BERLIN FÜR MATERIALIEN UND ENERGIE GESELLSCHAFT MIT BESCHRÄNKTER HAFTUNG, Berlin (DE)

(72) Inventors: Guillermo Antonio FARIAS BASULTO, Berlin (DE); Tobias BERTRAM, Berlin (DE); Rutger SCHLATMANN, Berlin (DE)

(73) Assignee: HELMHOLTZ-ZENTRUM BERLIN FÜR MATERIALIEN UND ENERGIE GESELLSCHAFT MIT BESCHRÄNKTER HAFTUNG, Berlin (DE)

(21) Appl. No.: 18/854,986

(22) PCT Filed: Apr. 4, 2023
(86) PCT No.: PCT/DE2023/100260

§ 371 Date: Oct. 8, 2024

(30) Foreign Application Priority Data
Apr. 8, 2022 (DE) 10 2022 108 554.6

(51) Int. Cl. H10F 19/35; H10F 10/172; H10F 19/40

(52) U.S. Cl. CPC H10F 19/35; H10F 10/172; H10F 19/40

(57) ABSTRACT

The invention relates to a 3T tandem solar cell, a tandem solar cell module and a method of manufacturing the same. The 3T tandem solar cell according to the invention comprises at least a first solar cell (11, 11′) comprising a first absorber layer (11-2, 11′-2) disposed between a first electrode (11-1, 11′-1) on a side of the first solar cell (11, 11′) facing the incident light (100), and a first transparent conductive layer (11-3, 11′-3) on a side of the first solar cell (11, 11′) facing away from the incident light (100), wherein the first solar cell (11, 11′) is disposed on a solar cell (12, 12′) having a second absorber layer (12-2, 12′-2) disposed between a second electrode (12-1, 12′-1) on a side of the second solar cell (12, 12′) facing away from the incident light (100) and a second transparent conductive layer (12-3, 12′-3) on a side of the second solar cell facing the incident light (100). According to the invention, a connecting layer (13) is arranged between the first and the second solar cell (11, 11′, 12, 12′), wherein the connecting layer (13) forms an electrically conductive connection between the first and the second solar cell (11, 11′, 12, 12′), and wherein the connecting layer (13) comprises an electrically conductive one-piece conductive element (13-3, 13′-3) configured and arranged to form the electrically conductive connection and wherein the conductive element (13-3, 13′-3) is embedded in an embedding means (13-2) while maintaining contact points (K1, K2, K3, K4, K5) respectively to the first and to the second transparent conductive layer (11-3, 11′-3, 12-3, 12′-3) and is connected to or integrally forms a third electrode (13-1, 13′-1) of the at least one tandem solar cell (10, 10′).

The invention relates to a 3T tandem solar cell, in particular for interconnection in a solar cell module, a tandem solar cell module and a method for manufacturing the 3T tandem solar cell.

Tandem solar cells are known in the prior art. A tandem solar cell comprises two solar cells—a first solar cell (“top cell”) and a second solar cell (“bottom cell”), which are stacked on top of each other, with the first solar cell absorbing light in a different wavelength range than the second solar cell. In this way, the energy yield is more efficient in the wavelength range in which the sunlight can be converted into electrical energy.

Thin-film solar cells have become popular candidates for tandem solar cells as they can be produced in cost-effective processes.

The first solar cell is usually contacted with a first electrode (“top electrode”) and the second solar cell with a second electrode (“bottom electrode”), which serve as (electrical) terminals (“T”), resulting in a so-called 2T tandem solar cell (2T from two terminals).

Tandem solar cells are available in various configurations for interconnection or equipped with connections for interconnection or for tapping current or voltage. In a so-called 2T tandem solar cell, the solar cells are connected in series, whereby the first and second electrodes are the contacts that provide the electrical voltage in one connection each for tapping. In a so-called 4T tandem solar cell, each solar cell is contacted separately and the electrical voltage and current for each cell is tapped individually, i.e. each cell has a complementary electrode.

A third configuration is referred to as a 3T tandem solar cell, which is constructed in such a way that a third electrode is provided as a connection by a connecting layer set up between the two solar cells, which contacts both the first and the second solar cell. 3T tandem solar cells are realized, for example, in the form of silicon perovskite tandem solar cells, in which the back contact can be divided into several contacts with selective n or p doping, e.g. as in so-called IBC (interdigitated back contact) interconnections. The main advantage of the 3T configuration is the possibility of mechanically connecting a top and a bottom solar cell, which makes it possible to tap the current (or voltage) generated between the top and bottom solar cell from the side (without selectively doping the bottom solar cell).

However, the production of 3T tandem solar cells for a tandem solar cell module comprising a plurality, but at least two, of such 3T tandem solar cells is a challenge, particularly with regard to the third electrode or the third connection. In addition, it would be advantageous to connect several 3T tandem solar cells in series in a module.

This problem was partially addressed by Talysa R Klein et al 2021 J. Phys. D: Appl. Phys. 54, 184002; https://doi.org/10.1088/1361-6463/abe2c4.

The authors of this paper present a tandem solar cell comprising a first solar cell and a second solar cell with a bonding layer disposed between the cells, the bonding layer including a plurality of silver-coated spheres configured and arranged to contact the first solar cell and the second solar cell. This type of contacting generally enables a 3T tandem solar cell. However, each contact of a ball with the first or second solar cell inevitably comprises an ohmic resistance. Moreover, since an electric current has to cross the contacts of the spheres with the contacting layers of the first and second solar cell several times in order to reach the edge of the tandem solar cell where the current can be tapped in a connection, the efficiency of such a configuration is significantly reduced due to ohmic losses at the contacts of the spheres. Furthermore, this approach only allows an electrical current to be tapped vertically. Lateral tapping is not possible.

There is therefore a need for an improved tandem solar cell with a 3T configuration.

The problem is solved by a 3T tandem solar cell according to claim 1, a tandem solar cell module according to the tandem solar cell of the invention according to claim 9 and a method for manufacturing a tandem solar cell module according to claim 13.

Advantageous embodiments are described in the dependent claims.

For the purposes of the invention and this description, the term connection hereinafter refers to a means of tapping a current or voltage from a tandem solar cell or a tandem solar cell module. In particular, this relates to electrodes and other means for conducting electric current comprised by the 3T tandem solar cell.

In the description of the invention, the term electrode refers to a means which is an electron conductor and interacts with a counter-electrode (anode-cathode), whereby the electrodes are electrically contacted with an absorber arranged directly or indirectly between them. Electrodes can always be used as terminals (“T”).

An absorber in the sense of the invention and this description relates to a material that absorbs light and in which charge carriers are generated by the absorption. To complete a solar cell, it is always intended here to complete an absorber in a suitable manner for generating electricity, e.g. by means of a p-n or p-i-n junction, if necessary by means of suitable doping, or e.g. by means of selective contacts.

Conductive is always used in the sense of electrically conductive and refers to an electrical conductivity of ≥1-10⁵ S/m.

The 3T tandem solar cells and tandem solar cell modules according to the invention are not limited by the following description and the patent claims to the explanations given here regarding the layers provided. The person skilled in the art is free to design them with further functional layers.

A first aspect of the invention relates to a 3T tandem solar cell comprising at least the following components:
a first solar cell comprising at least a first absorber layer disposed between a first electrode disposed on a side of the first solar cell which, in use, faces an incident light and a first transparent conductive layer disposed on a side of the first solar cell which, in use, faces away from the incident light,
a second solar cell comprising a second absorber layer disposed between a second electrode disposed on a side of the second solar cell which, in use, faces away from the incident light and a second transparent conductive layer disposed on a side of the second solar cell which, in use, faces the incident light, and
a connecting layer provided between the first and second solar cells, the connecting layer forming an electrically conductive connection between the first solar cell and the second solar cell, wherein the connecting layer comprises at least one electrically conductive, one-piece conductive element, and wherein the at least one one-piece conductive element is embedded in an embedding means while maintaining a plurality of contact points to the first and second transparent conductive layers, respectively, and wherein the at least one one-piece conductive element forms or is connected to a third electrode of the 3T tandem solar cell.

The 3T tandem solar cell according to the invention provides a robust improvement of the 3T tandem solar cells known from the prior art. The use of at least one one-piece conductive element embedded in the compound layer, which on the one hand contacts the first and the second solar cell by means of several contact points and on the other hand forms the third electrode or is connected to it, enables the 3T tandem solar cell according to the invention to be produced quickly and reliably.

In particular, the 3T tandem solar cell is a thin-film tandem solar cell in which the absorber layers are designed as thin films. Thin layers are usually defined as layers in the range of a few nanometers (1 nm) to a few tens of micrometers (50 μm).

The first electrode can be designed as a layer that covers the first absorber layer. In this case, the first electrode, which faces the incidence of light during operation of the 3T tandem solar cell, is transparent. For example, the transparent first electrode may consist of or comprise indium zinc oxide (IZO) or another transparent conductive oxide (TCO).

Alternatively, the first electrode can be non-transparent and consist of a metallic compound, for example, and in this case is not designed as a layer so that light can still enter the 3T tandem solar cell.

Similarly, the second electrode can be transparent, but can also comprise a metal or a metal compound, such as molybdenum, which can also be designed as an electrode in the form of contact fingers. The second electrode can also be designed as a layer that covers the second absorber layer on the side facing away from the incident light.

The first solar cell is configured to absorb light in a first wavelength range of the electromagnetic spectrum and to generate charge carriers in response to the absorption of the light. The second solar cell is configured to absorb light in a second wavelength range of the electromagnetic spectrum and to generate charge carriers in response to the absorption of the light. The first and second wavelength ranges are different from each other. In particular, the first wavelength range is blue-shifted relative to the second wavelength range. However, it can also be red-shifted relative to the second wavelength range.

The embedding agent is, for example, an electrically insulating polymer or, advantageously, an electrically insulating thermoplastic. All materials that have a specific resistance of ≥10¹⁰ Ω·cm are to be regarded as electrically insulating in the sense of the invention.

The third electrode can be formed by a busbar that is connected to one or more ends of the at least one conductive element or conductive elements, or by the at least one one-piece conductive element itself.

The at least one one-piece conductive element can be a metallic conductor element that is formed a single one-piece. In particular, the conductive element can be formed as a wire, which can also be formed as a stranded wire having at least two strands. The arrangement of several wires or strands is also covered by the invention.

The 3T tandem solar cell is connected in several embodiments, in particular to form a tandem solar module, or is implemented directly in a tandem solar module, as also corresponds to a second aspect of the invention.

In particular, in a tandem solar cell module with more than one 3T tandem solar cell, the third electrode of the last 3T tandem solar cell in a row of tandem solar cells is accessible for external contacting and forms the third electrode there or can be contacted with such an electrode, thereby forming a third terminal in the solar module.

The at least one one-piece conductive element makes contact with the first and second solar cell in a 3T tandem solar cell through several (n≥2) contact points and enables an accessible third connection (terminal). The contact points are retained when the at least one one-piece conductive element is embedded.

The contact points can be of different sizes and, if necessary, optimized in terms of size and number with regard to the resistances formed.

In the event that the third electrode of a 3T tandem solar cell is not the last third electrode in the tandem solar cell module of the series-connected 3T tandem solar cells, the third electrode cannot be accessible from outside the junction layer or the module and therefore does not form the third connection.

Similarly, the first electrode of the first tandem solar cell can form the first terminal and the second electrode of the first tandem solar cell can form the second terminal, so that the tandem solar cell module always comprises three terminals (3T).

The 3T tandem solar cell can be formed monolithically, i.e. the first and second solar cells and the connecting layer are manufactured in one piece.

According to one embodiment of the invention, the embedding agent comprises ethylene vinyl acetate (EVA, CAS-NR: 24937-78-8) or a poly-olefin elastomer (POE), wherein the embedding agent also imparts mechanical stability to the tandem solar cell in particular.

According to another embodiment of the invention, the first absorber layer comprises a first perovskite layer or a first chalcopyrite absorber layer, in particular a CIGS layer, and/or wherein the second absorber layer comprises a second chalcopyrite absorber layer, in particular a CIGS layer, or a second perovskite layer.

In particular, the first absorber layer can have a higher band gap than the second absorber layer.

Alternatively, the first or second absorber layer is or comprises amorphous or crystalline silicon.

In the context of the present patent specification, the term “perovskite” refers in particular to a molecular structure with the general molecular formula ABX3, which is crystallized in the structure of the mineral perovskite, and which has, for example, methylammonium (MA), cesium (Cs) and/or formamidinium (FA) as component A, while component B is often given by lead (Pb). X stands, for example, for iodine (I), bromine (Br) and/or chlorine (Cl) or a mixture of these elements.

The first or second absorber layer comprising perovskite may have the molecular formula Cs_{0.05} (FA_{0.83} MA)_{0.170,95} Pb(I_{0.83} Br)_{0.173}. Variations in the relative proportions of the components can also provide a functional absorber layer.

It should be noted that the absorber layer-such as chalcopyrite, CIGS or perovskite—may further comprise a plurality of layers of different materials and compounds deposited on an absorber material so that the solar cell generates charge carriers.

For example, in the case where the second, i.e. bottom solar cell comprises chalcopyrite, e.g. CIGS, in the second absorber layer, additional layers comprising the second absorber layer may be, for example, CdS, i-ZnO and/or ZnO:Al.

In the case that the first, i.e. the top solar cell comprises perovskite in the first absorber layer, the additional layers in the first absorber layer can be one or more of e.g. NiOₓ, PTAA, C₆₀, SnO₂, IZO (indium zinc oxide), LiF.

These additional layers can contribute to improved charge carrier extraction and conduction and/or prevent the so-called “shunting” of the solar cells of the tandem solar cell. For example, a NiOₓ underlayer can be applied to the first solar cell for this purpose.

All absorber layers can be designed as thin layers in particular.

According to another embodiment of the invention, the first absorber layer may comprise a self-assembled monolayer (SAM) as a hole-conducting layer, wherein the SAM comprises, for example, 2PACz (CAS No.: 20999-38-6) and/or MeO-2PACz (Cas No.: 2377770-18-6).

The absorbers in the solar cells covered by the 3T tandem solar cell can be formed, for example, in a combination of perovskite as the first absorber layer and CIGS as the second absorber layer.

Another possible combination is chalcopyrite, like CIGS, as the first absorber layer and perovskite as the second absorber layer.

The combination of absorber layers in the tandem solar cell is also possible as chalcopyrite, such as CIGS, as the first and second absorber layer or perovskite as the first and second absorber layer.

The at least one one-piece conductive element contacts the first transparent conductive layer and the second transparent conductive layer respectively at a plurality of contact points with both conductive layers, wherein an electric current of charge carriers in the at least one one-piece conductive element generated by the first absorber layer and the second absorber layer can or does flow towards the third electrode without returning back to the first or second transparent conductive layer, in particular such that a cumulative contact resistance of the tandem solar cell is reduced or minimized.

In the prior art (Talysa R Klein et al 2021), in which the compound layer comprises a plurality of silver-coated spheres, the charge carriers cannot flow toward a third electrode in the spheres without traveling back and forth along the contacts formed by the spheres with the conductive layers, causing them to have comparatively higher resistance and ohmic losses.

According to another embodiment of the invention, the at least one one-piece conductive element extends in a plane of the connecting layer which extends substantially parallel to a surface of the at least one tandem solar cell facing the incident light.

The term “parallel” in the context of a layer refers in particular to local parallelism, as the layers of the tandem solar cell can have a comparatively rough surface and layer structure when viewed under a microscope. For this reason, the term “parallel” should be interpreted in a broad sense.

According to another embodiment of the invention, the at least one one-piece conductive element extends within the connecting layer, in particular such that the at least one conductive element contacts the first and the second transparent conductive layer several times each, thereby forming the plurality of contact points.

Therefore, the at least one one-piece conductive element can extend in a meandering manner within the connecting layer, in particular such that a plurality (several, n≥2) of contact points is formed. This embodiment enables fail-safe contacting of the first and second transparent conductive layers due to the redundancy provided by a plurality of contact points.

According to another embodiment of the invention, in regions within the first solar cell in which the first absorber layer is neither connected to or contacted by the first conductive layer nor connected to or contacted by the first electrode, a first electrically insulating layer is arranged at the first absorber layer, so that in these regions the first absorber layer is electrically insulated from the connecting layer, and/or wherein in regions within the second solar cell in which the second absorber layer is neither connected to or contacted by the second conductive layer nor connected to or contacted by the second electrode, a second electrically insulating layer is arranged at the second absorber layer, so that in these regions the second absorber layer is electrically insulated from the connecting layer.

This embodiment enables complete electrical isolation of the first and/or second absorber layer from the connecting layer, minimizing the risk of a short circuit between the components of the tandem solar cell.

The first and/or second insulating layer can comprise intrinsic materials such as silicon oxide (SiOₓ) or undoped ZnO.

According to another embodiment of the invention, the first insulating layer is arranged such that the first electrode is electrically insulated from the at least one one-piece conductive element and/or wherein the second insulating layer is arranged such that the second electrode is electrically insulated from the at least one conductive element.

In particular, the first and/or the second insulating layer of the tandem solar cell are arranged such that at least one contacting area remains free for a third electrode from another tandem solar cell, in particular such that this third electrode can be contacted with the first and/or the second electrode of the tandem solar cell. In this way, a series connection can be established between two tandem solar cells.

The 3T tandem solar cell is also embodied with a transparent top protective layer, also referred to by the skilled person as a superstrate, disposed on the first solar cell, wherein in use the top protective layer faces or is configured to face the incident light, and wherein the at least one tandem solar cell further comprises a bottom substrate disposed on the second solar cell, wherein in use the bottom substrate faces or is configured to face away from the incident light.

The top and bottom substrates can each be designed as a flexible layer so that the tandem solar cell or a corresponding tandem solar cell module can adapt or is adapted to a curved or flexible surface.

For this purpose, the first and second substrates may comprise a transparent polymer layer.

However, the top and bottom substrates can also be inflexible, so that a rigid tandem solar cell or a rigid tandem solar cell module is formed.

For this purpose, the top and bottom substrates can comprise glass.

According to a second aspect of the invention, at least a first and a second 3T tandem solar cell form a tandem solar cell module, wherein the at least first and the at least second tandem solar cell are electrically connected in series and wherein the electrode formed or connected to the at least one one-piece conductive element in the connecting layer of the first tandem solar cell is electrically connected to the first and/or the second electrode of the second tandem solar cell.

In particular, the tandem solar cell module according to the invention can be manufactured monolithically, i.e. the first and second tandem solar cells are each formed monolithically in one process.

The tandem solar cell module according to this second aspect of the invention teaches an improved way of connecting the two tandem solar cells in series by utilizing the comparatively low complexity of the connecting layer with the at least one one-piece conductive element.

While the at least first and second 3T tandem solar cells each comprise at least one separate one-piece conductive element, the third electrode of the first 3T tandem solar cell contacts the second tandem solar cell, resulting in a series connection.

In particular, the at least one one-piece conductive element of the at least first 3T tandem solar cell and the at least one one-piece conductive element of the at least second 3T tandem solar cell are not directly electrically connected to each other. In particular, the conductive elements are insulated from each other by the electrically insulating embedding agent.

According to one embodiment, the third electrode of the first 3T tandem solar cell and the at least one one-piece conductive element of the second 3T tandem solar cell are electrically insulated from each other, wherein the at least one conductive element and the third electrode are insulated by the embedding agent of the compound layer of the first and/or second 3T tandem solar cell, so that a charge carrier current cannot flow directly from the third electrode of the first 3T tandem solar cell to the at least one conductive element of the second 3T tandem solar cell.

This embodiment enables a series connection of at least two 3T tandem solar cells, which are formed in one piece-monolithically.

In the monolithic embodiment of a 3T tandem solar cell module according to the invention, the first electrodes of the at least first and second 3T tandem solar cells are electrically insulated from each other by means of a first insulating section which is arranged between the first electrodes in such a way that the first absorber layer of the first 3T tandem solar cell is electrically insulated from the first absorber layer of the second 3T tandem solar cell, electrically insulated from one another, and wherein the second electrodes of the first and second 3T tandem solar cells are electrically insulated from one another by means of a second insulating section which is arranged between the second electrodes in such a way that the second absorber layer of the first 3T tandem solar cell is electrically insulated from the second absorber layer of the second 3T tandem solar cell.

In particular, the first and/or the second electrode are physically separated from each other at the first and/or the second insulating cut, i.e. by means of a groove produced by a mechanical tool or an optical scribing, such as to be realized by laser ablation.

An insulating cut, also referred to as a parting line, is designed in the sense of the invention in such a way that the layers separated by it, in particular the electrodes, are electrically insulated from each other.

This embodiment enables the production of a plurality of 3T tandem solar cells which are produced, for example, on one piece substrates and layers and which are suitably electrically insulated so that the plurality can be produced comparatively effortlessly despite being formed in one piece substrates and layers.

According to another embodiment of the invention, the first electrodes of the at least first and second 3T tandem solar cells are integrated into a solar cell module, e.g. formed as a first electrode substrate and separated by means of a mechanical scribing or laser ablation process, whereby the first insulating section is produced and, in particular, the at least two first electrodes are formed, and wherein the second electrodes are integrated into the at least first and second 3T tandem solar cells, e.g. formed as a second electrode substrate and separated by means of a mechanical scribing or laser ablation process, whereby the second insulating section is produced and, in particular, the second electrodes of the at least two 3T tandem solar cells are formed. e.g. as a second electrode substrate and separated by means of a mechanical scribing or laser ablation process, whereby the second insulating cut is produced and, in particular, the second electrodes of the at least two 3T tandem solar cells are formed.

This embodiment specifies the advantages and the possible manufacturing options in relation to one piece electrode substrates.

According to an alternative embodiment of the invention, the tandem solar cell module comprises at least a first and a second 3T tandem solar cell, which are electrically connected in parallel.

According to a third aspect of the invention, a method of manufacturing a tandem solar cell module comprising at least two 3T tandem solar cells according to the invention is disclosed, wherein the method essentially comprises the following steps:
a) Production of a large number of first, i.e. top solar cells on a superstrate;
b) Manufacture of a plurality of second, i.e. bottom solar cells on a substrate;
c) connecting the first and second solar cells via a connecting layer, the connecting layer comprising an electrically insulating embedding means and, for each pair of first and second solar cells of a 3T tandem solar cell, at least one one-piece conductive element, each conductive element being designed and arranged to form or be electrically contacted with a third electrode.

Detailed manufacturing steps are disclosed below.

It is emphasized that the top and bottom solar cells are manufactured individually and separately, e.g. by using a substrate process for the second (bottom) solar cells comprising e.g. CIGS and a superstrate process for the first (top) solar cells comprising e.g. perovskite. Once the top and bottom solar cells are formed, the solar cells are sandwiched together, which has advantages over tandem solar modules, which are formed layer by layer in a monolithic process.

The detailed steps involved in the process are as follows:
i) cutting a first electrode substrate to form the first electrodes of the at least first and second 3T tandem solar cells, thereby forming at least a first insulating section between the first electrodes;
ii) cutting a second electrode substrate to form the second electrodes of the at least first and second 3T tandem solar cells, thereby forming at least a second insulating section between the second electrodes;
iii) producing, e.g. by coating or growing, a first absorber layer of the at least first and second 3T tandem solar cells in one piece on the first electrodes, whereby the first insulating section can be filled with the material of the first absorber layer;
iv) producing, e.g. by coating or growing, a second absorber layer of the at least first and second 3T tandem solar cells in one piece on the second electrodes, whereby the second insulating section can be filled by the material of the second absorber layer;
v) Creating a first transparent conductive layer in one piece on the first absorber layer;
vi) Creating a second transparent conductive layer in one piece on the second absorber layer;
vii) cutting the one piece first absorber layer and the one piece first transparent conductive layer by means of a mechanical scribing or laser ablation process, so that at least two first solar cells are produced;
viii) cutting the one piece second absorber layer and the one piece second transparent conductive layer by means of a mechanical scribing or laser ablation process, so that at least two second solar cells are produced;
ix) arranging and aligning an at least first one-piece conductive element and a separate at least second conductive element, and embedding the conductive elements with an embedding agent between the first and second solar cells so that the solar cells are arranged one above the other and so that the at least first one-piece conductive element can form a plurality of contact points with the first and second transparent conductive layers of a first 3T tandem solar cell, respectively, and so that the at least second one-piece conductive element can form a plurality of contact points with the first and second transparent conductive layers of the second 3T tandem solar cell, respectively;
x) heating the bonding layers of embedding agent and conductive elements so that the embedding agent is adhesively bonded to the first and the second solar cell and so that the at least first and the at least second one-piece conductive element form several contacts with the first and the second transparent conductive layer, respectively.

It should be noted that, particularly in steps iii) and iv), the insulating sections are not imparted any electrical conductivity by the—potential—filling with the material of the absorber layers.

It should also be noted that the term “the first solar cell” is used synonymously with “the top solar cell”. Similarly, the term “the second solar cell” is used synonymously with “the bottom tandem solar cell”. The adjectives “top” and “bottom” refer to the incidence of light, with the side of the incidence of light meaning the top side.

The method for manufacturing the tandem solar cell module enables fast and large-scale manufacturing, wherein the module comprises two or more series-connected 3T tandem solar cells having three connections according to the invention. In particular, the top and bottom solar cells are manufactured individually and separately, e.g. by applying a substrate process for the second (bottom) solar cells, e.g. comprising CIGS, and a superstrate process for the first (top) solar cells, e.g. comprising perovskite. Once the top and bottom solar cells are formed, the solar cells are sandwiched together by the interconnect layer and contacted by the one-piece conductive elements.

To cut the insulating cut separating the electrodes, for example, a scoring method can be used, as is usually used for P1 structuring.

According to another embodiment, the at least first and the at least second one-piece conductive elements comprise a third electrode in which they are connected to or form an integral part thereof, wherein the third electrode of a first 3T tandem solar cell forms an electrical contact with the first and/or the second electrode of a second tandem solar cell in a separation cut between the first absorber layers and the second absorber layers, in particular in the case where the third electrode is not the last of a series of tandem solar cells, i.e. is not the third connection electrode. A separation cut separates the 3T tandem solar cells in a tandem solar cell module so that they are present as individual 3T tandem solar cells in the module, which are nevertheless interconnected to form the module. The separation cuts usually extend from the top electrode, without encompassing it, to the bottom electrode, without encompassing it. These latter separation cuts can be formed during process steps vii) and viii).

The third electrode can comprise a busbar or an electrically conductive element to which the at least one one-piece conductive element is connected.

Similarly, the third connection electrode may comprise or be a busbar to which the at least one one-piece conductive element is connected.

According to another embodiment of the invention, after step viii), a first and a second insulating layer are produced, for example by a printing or other deposition process, in particular after the conductive layers and the exposed electrode regions have been masked by a protective masking material.

### EMBODIMENT EXAMPLE

An embodiment example is described below in conjunction with two figures.

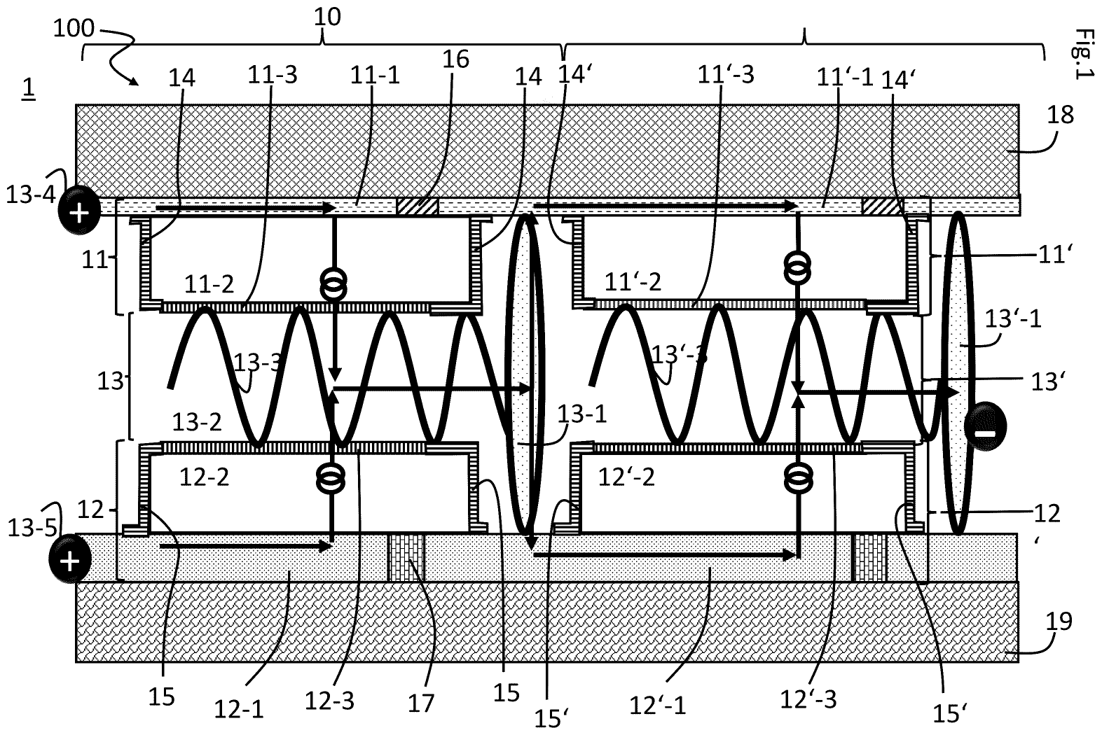

FIG. 1: Schematic cross-sectional view of a tandem solar cell module with two 3T tandem solar cells connected in series according to the invention

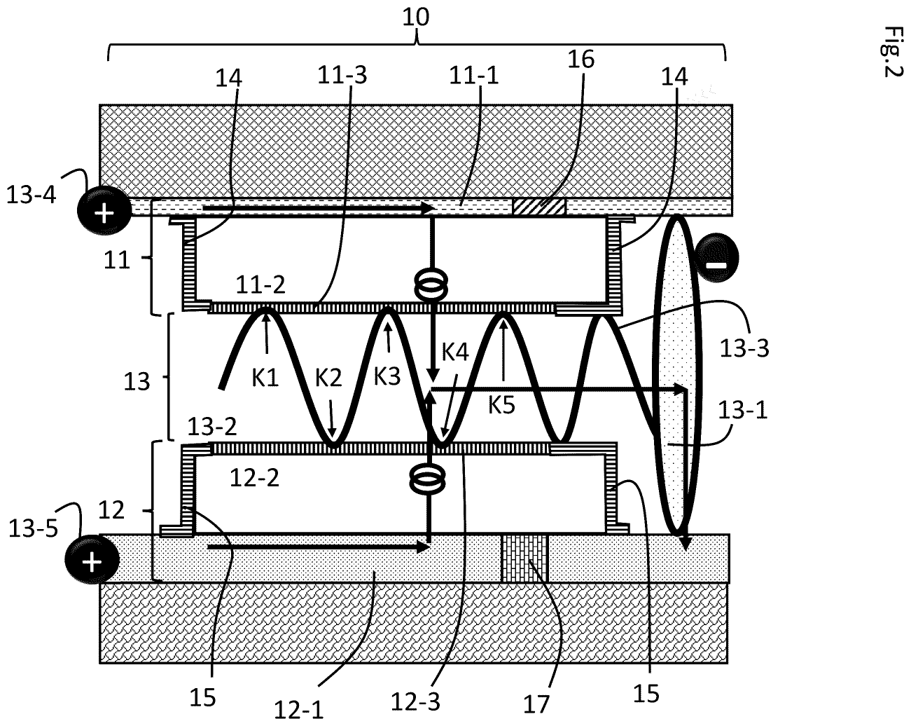

FIG. 2: Section from FIG. 1

FIG. 1 shows a schematic cross-sectional view of a tandem solar cell module comprising a first and a second 3T tandem solar cell 10, 10′, which are connected in series. The first and second 3T tandem solar cells 10, 10′ each comprise two solar cells 11, 11′, 12, 12′ arranged one above the other (tandem arrangement). The terms “one above the other”, “top side”, “bottom side” etc. refer in particular to a direction of the 3T tandem solar cells 10, 10′ in relation to the incident light 100, e.g. sunlight. According to this term, the top side refers to a side facing the incident light 100, or at least closer to this side, on which the incident light 100 strikes the 3T tandem solar cell or module when these are set up and aligned for operation.

Similarly, the term “bottom side” refers to the side facing away from the light.

Consequently, the term “on top of each other” or similar terms refer to the direction, also called z-axis, pointing from the bottom side to the top side of the 3T tandem solar cell 10, 10′ or module 1.

The 3T tandem solar cells 10, 10′ and the tandem solar cell modules 1 comprise a first extension direction (z-axis) that extends from the bottom to the top side.

Along this direction of extension, the layers and electrodes 11-1, 11′-1, 12-1, 12′-1 of the 3T tandem solar cells 10, 10′ are planar parallel to the plane spanned by the x and y axes orthogonal to the direction of extension.

FIG. 1 shows a cross-section along the x- and z-axis. The illustration is not to scale and merely serves as a guide to the general arrangement of the individual components of the 3T tandem solar cells 10, 10′ or the tandem solar cell module 1.

Along the y-axis, the cross-section can simply be extruded orthogonally to the x-z plane to obtain the 3D structure of the tandem solar cell module 1/the 3T tandem solar cells 10, 10′.

However, it should be noted that the x, y and z axes can only provide a local coordinate system, which can vary in orientation if the tandem solar cell module is curved.

The general sequence of layers in the tandem solar cell module 1 in the embodiment example can be summarized as follows, starting from the top:
(optional) a transparent protective layer 18
a first solar cell 11,11′ comprising at least the following:
a) first transparent electrode 11-1, 11′-1,
b) a first absorber layer 11-2, 11′-2,
c) a first transparent conductive layer 11-3, 11′-3,
a connecting layer 13 comprising at least one electrically conductive one-piece conductive element 13-3, 13′-3 for each tandem solar cell 10, 10′ of the module 1, which is embedded in an embedding means 13-2;
a second solar cell 12, 12′, comprising at least the following:
a) a second transparent conductive layer 12-3, 12′-3,
b) a second absorber layer 12-2, 12′-2,
c) a second electrode 12-1, 2′-1
a bottom substrate 19.

the transparent protective layer 18 may consist of glass or a flexible transparent layer, such as a polymer. The term “transparent” refers in particular to the property of the material to be transparent to electromagnetic radiation in the wavelength ranges in which the first and second absorber layers absorb the radiation and convert the radiation into the charge carriers of the respective solar cell.

For this purpose, the first electrode 11-1, 11′-1 can be made of indium zinc oxide (IZO) or indium tin oxide (ITO) or another transparent and electrically conductive material.

The first absorber layer 11-2, 11′-2 may comprise a plurality of different layers forming the absorber layer 11-2, 11′-2. Typical compositions, layers and layer sequences are known and are not of specific relevance to the invention. For example, the first absorber layer 11-2, 11′-2 may comprise a CIGS or a perovskite layer.

The first transparent conductive layer 11-3, 11′-3 substantially forms an electrode of the first solar cell 11, 11′. The first transparent conductive layer 11-3, 11′-3 may comprise or consist of ZnO:Al and may generally comprise a transparent conductive oxide (TCO).

Similarly, the second transparent conductive layer 12-3, 12′-3 forms an electrode of the second solar cell 12, 12′. The second transparent conductive layer 12-3, 12′-3 may comprise or consist of ZnO:Al and may generally comprise a transparent conductive oxide (TCO).

For contacting the first and second solar cells 11, 11′, 12, 12′, the connecting layer 13 in each 3T tandem solar cell comprises a one-piece conductive element 13-3, 13′-3, in particular a wire, which electrically contacts the first and second solar cells 11, 12, 11′, 12 by forming several contact points K1, K2, K3, K4, K5 on each of the transparent conductive layers 11-3, 11′-3, 12-3, 12′-3. In FIG. 2, a section of the tandem solar cell module of FIG. 1 (a tandem solar cell 10) is shown for a better overview, in which the contact points K1, K2, K3, K4, K5 of the at least one one-piece conductive element 13-3, 13′-3 of the at least one one-piece conductive element 13-3 of this tandem solar cell are shown by way of example. This inventive type of contacting enables the charge carriers generated by the first and second solar cells 11, 11′, 12, 12′ to be conducted to the third electrode 13-1, 13′-1. In particular, the conductive element 13-2, 13′-2 contacts the transparent conductive layer 11-3, 11′-3, 12-3, 12′-3 at a plurality of contact points K1, K2, K3, K4, K5. In the example shown, a first and second 3T tandem solar cell 10, 10′ are electrically connected in series. Therefore, the third electrode 13-1 of the first 3T tandem solar cell 10 contacts the first and second electrodes 11′-1, 12′-1 of the second 3T tandem solar cell 10′, with the third electrode 13′-1 of the second tandem solar cell 10′ forming a connection electrode, i.e. the third connection 13′-1.

Alternatively, the one-piece conductive element 13-2, 13′-2 may continuously contact the first and second solar cells 11, 12, 11′, 12 so that essentially only one contact section is formed. (This embodiment is not shown.)

The tandem solar cell module 1 also provides a first and a second connection, namely at the first and the second electrode of the first tandem solar cell or at a conductive connection attached thereto (not shown).

Of course, this concept of interconnection of 3T tandem solar cells according to the invention can extend to three or more 3T tandem solar cells 10, 10′ connected in series, as long as the first tandem solar cell 10 provides the first and the second connection 13-4, 13-5 and the third electrode 13′-1 of the 3T last tandem solar cell in series forms the third connection 13′-1. Furthermore, each third electrode 13-1, 13′-1 (except for the last one in the series) of a 3T tandem solar cell 10, 10′ of such a tandem solar cell module 1 contacts the first and/or the second electrode of a subsequent tandem solar cell connected in series in the module 1.

Importantly, the one-piece conductive elements 13-3, 13′-3 in the first and second 3T tandem solar cells 10, 10′ and more generally all 3T tandem solar cells 10, 10′ of such a module 1 are not in direct electrical contact with each other, so that the conductive elements 13-3, 13′-3 can be isolated from each other by an embedding means comprised by the connecting layer 13. This allows the charge carriers to move along the intended path (—OO—>) through the tandem solar cell module and prevents a short circuit.

The one-piece conductive element 13-3, 13′-3 can be designed as a wire, with the third electrode 13-1, 13′-1 of each or the last (e.g. second) 3T tandem solar cell 10, 10′ being designed as a busbar to which the conductive element 13-3, 13′-3, e.g. the wire, is connected.

The busbar is connected either to the first and/or the second electrode 11-2, 11′-2, 12-2, 12′-2 of the respective subsequent 3T tandem solar cell 10, 10′, whereby the busbar of the last tandem solar cell 10′ at least partially forms the third connection (electrode) 13′-1.

The connecting layer 13 comprises an embedding agent 13-2, which is electrically insulating and firmly connects the two solar cells 11, 11′, 12, 12′ of each 3T tandem solar cell 10, 10′. The assembled tandem solar cell module 1 is thus formed in one piece or monolithically.

Bringing the first and second solar cells 11, 11′, 12, 12′ together is achieved in particular by heating the bonding layer 13 with the embedding agent 13-2 and the one-piece conductive element 13-3, 13′-3 so that it acts like an insulating adhesive. In the connecting layer 13, the conductive element 13-3, 13′-3 meanders, for example, between the first and second transparent conductive layers 11-3, 11′-3, 12-3, 12′-3 and thus forms the contact points K1, K2, K3, K4, K5.

Each one-piece conductive element 13 of each 3T tandem solar cell 10, 10′ is electrically insulated from one another.

The first electrodes 11-1, 11′-1 and the second electrodes 12-1, 12′-1 of the tandem solar cell module 1 are each electrically separated by an insulating cut 16, 17 (corresponding to a P1 structuring) between the first electrode 11-1, 11′-1 and the second electrode 12-1, 12′-1 respectively. These non-conductive insulating cuts 16, 17 can be formed by a mechanical scribing or an optical process, such as laser ablation. The insulating cuts 16, 17 are set upstream, upstream or above the contacting portions of the third electrode 13-1, 13′-1 with the first and/or the second electrode 11′-1, 12′-1 of the second tandem solar cell 10′. In this way, the solar cells 11, 11′, 12, 12′ and the 3T tandem solar cells 10, 10′ are connected in series with each other in a tandem solar cell module.

To prevent a short circuit, the first and second absorber layers 11-2, 11′-2, 12-2, 12′-2 of each tandem solar cell 10, 10′ in a tandem solar cell module can be covered by a first insulating layer 14, 14′ arranged at the first absorber layers 11-2, 11′-2 and a second insulating layer 15, 15′, which is arranged at the second absorber layer 12-2, 12′-2, so that the absorber layers 11-2, 11′-2, 12-2, 12′-2 are electrically insulated in regions which are not to be connected to the first, second or third electrode 11-1, 11′-1, 12-1, 12′-1, 13-1, 13′-1 and to the one-piece conductive element 13-3, 13′-3. These insulating layers 14, 14′, 15, 15′ thus provide a means of making the tandem solar cell module short-circuit-free. These regions are located or extend, for example, along the z-direction of the absorber layers 11-2, 11′-2, 12-2, 12′-2 and the portions of the first absorber layers 11-2, 11′-2 which face away from the top of the tandem solar cell 10, 10′ and which are not covered by the transparent conductive layer 11-3, 11′-3.

Similarly, these regions may be located further away or extend along the portions of the second absorber layers 12-2, 12′-2 that face the top of the tandem solar cell 10, 10′ and that are not covered by the transparent conductive layer 12-3, 12′-3.

A first electrically insulating layer 14, 14′ is arranged at the first absorber layer 11-2, 11′-2, so that in these regions the first absorber layer 11-2, 11′-2 is electrically insulated from the connecting layer 13, and/or wherein in regions inside the second solar cell 12, 12′, in which the second absorber layer 12-2, 12′-2 is neither connected to or contacted by the second conductive layer 12-3, 12′-3 or is contacted by the latter nor is connected to the second connecting electrode 13′-1 or is contacted by the latter, a second electrically insulating layer 15, 15′ is arranged at the second absorber layer 12-2, 12′-2, so that in these regions the second absorber layer 12-2, 12′-2 is electrically insulated from the connecting layer 13.

The absorber layers 11-2, 11′-2, 12-2, 12′2 and the transparent, conductive layers 11-3, 11′-3, 12-3, 12′-3 are also separated from each other by a separation cut, forming the individual 3T tandem solar cells. The separation cut is not shown for reasons of clarity but can be clearly identified by its position and function. The separation cut can be made using a mechanical scribing or laser ablation process.

This embodiment enables complete electrical isolation of the first and/or second absorber layer 11-2, 11′-2, 12-2, 12′-2 from the connecting layer 13, so that the risk of a short circuit between the components of the tandem solar cell 10, 10′ is minimized.

1. 3T tandem solar cell (10, 10′), comprising at least:
a first solar cell (11, 11′) comprising at least a first absorber layer (11-2, 11′-2) arranged between a first electrode (11-1, 11′-1) on a side of the first solar cell (11, 11′) facing the incident light (100) and a first transparent conductive layer (11-3, 11′-3) on a side of the first solar cell (11, 11′) facing away from the incident light (100),
a second solar cell (12, 12′) comprising at least a second absorber layer (12-2, 12′-2) arranged between a second electrode (12-1, 12′-1) on a side of the second solar cell (12, 12′) facing away from the incident light (100) and a second transparent conductive layer (12-3, 12′-3) on a side of the second solar cell facing the incident light (100);
a connecting layer (13) arranged between the first and the second solar cell (11, 11′, 12, 12′), the connecting layer (13) forming an electrically conductive connection between the first and the second solar cell (11, 11′, 12, 12′);
characterized in that
the connecting layer (13) comprises at least one electrically conductive, one-piece conductive element (13-3, 13′-3), and wherein the at least one one-piece conductive element (13-3, 13′-3) is embedded in an embedding means (13-2) while maintaining contact points (K1, K2, K3, K4, K5) to the first and to the second transparent conductive layer (11-3, 11′-3, 12-3, 12′-3) respectively, and the at least one one-piece conductive element (13-3, 13′-3) is connected to or forms a third electrode (13-1, 13′-1).

2. The 3T tandem solar cell (1) according to claim 1, wherein the embedding agent comprises ethylene-vinyl acetate (EVA) or a poly-olefin elastomer (POE).

3. The 3T tandem solar cell according to claim 1, wherein the first absorber layer (11-2, 11′-2) comprises a first thin film material layer such as a first perovskite layer or a first chalcopyrite absorber layer, and/or wherein the second absorber layer (12-2, 12′-2) comprises a second thin film material layer such as a second chalcopyrite absorber layer or a second perovskite layer.

4. 3T tandem solar cell (1) according to claim 1, wherein the at least one one-piece conductive element (13-3, 13′-3) contacts the first and the second transparent conductive layer (11-3, 11′-3, 12-3, 12′-3) each at several contact points (K1, K2, K3, K4, K5), wherein an electric current of charge carriers in the at least one one-piece conductive element (13-3, 13′-3) can flow to the third electrode (13-1, 13′-1), in particular without returning to the first or second transparent conductive layer (11-3, 11′-3, 12-3, 12′-3) of the at least one tandem solar cell (10, 10′).

5. The 3T tandem solar cell (1) according to claim 1, wherein the at least one one-piece conductive element (13-3, 13′-3) extends in a plane of the connecting layer (13) that extends substantially parallel to a surface of the at least one tandem solar cell (10, 10′) facing the incident light (100).

6. 3T tandem solar cell (1) according to claim 1, wherein in regions within the first solar cell (11, 11′) in which the first absorber layer (11-2, 11′-2) is connected neither to the first conductive layer (11-3, 11′-3) nor to the first electrode (11-1, 11′-1), a first electrically insulating layer (14, 14′) is arranged at the first absorber layer (11-2, 11′-2), so that in these regions the first absorber layer (11-2, 11′-2) is electrically insulated from the connecting layer (13), and/or in regions within the second solar cell (12, 12′) in which the second absorber layer (12-2, 12′-2) is connected neither to the second conductive layer (12-3, 12′-3) nor to the second electrode (12-1, 12′-1), a second electrically insulating layer (15, 15′) is arranged at the second absorber layer (12-2, 12′-2), so that in these regions the second absorber layer (12-2, 12′-2) is electrically insulated from the connecting layer (13).

7. The 3T tandem solar cell (1) according to claim 6, wherein the first insulating layer (14, 14′) is arranged such that the first electrode (11-1, 11′-1) is electrically insulated from the at least one one-piece conductive element (13-3, 13′-3) and/or wherein the second insulating layer (15, 15′) is arranged such that the second electrode (12-1, 12′-1) is electrically insulated from the one-piece conductive element (13-3, 13′-3).

8. Tandem solar cell module (1) comprising at least two 3T tandem solar cells according to claim 1, wherein the first and the second tandem solar cell (10, 10′) are electrically connected in series and wherein the third electrode (13-1) of the first tandem solar cell (10) is electrically connected to the first and/or the second electrode (11′-1, 12′-1) of the second tandem solar cell (10′).

9. Tandem solar cell module (1) according to claim 8, wherein the third electrode (13-1) of the first tandem solar cell (10) and the at least one one-piece conductive element (13′-3) of the second tandem solar cell (10′) are electrically insulated from one another, so that a charge carrier current cannot flow directly from the third electrode (13-1) of the first tandem solar cell (10) to the at least one conductive element (13′-3) of the second tandem solar cell (10′).

10. Tandem solar cell module (1) according to claim 8, wherein the first electrodes (11-1, 11′-1) of the first and the second tandem solar cell (10, 10′) are electrically insulated from each other by means of a first insulating cut (16), which is arranged such that the first absorber layer (11-2) of the first tandem solar cell (10) is electrically insulated from the first absorber layer (11′-2) of the second tandem solar cell, and wherein the second electrodes (12-1, 12′-1) of the first and second tandem solar cells (10, 10′) are electrically insulated from each other by means of a second insulating section (17), which is arranged such that the second absorber layer (12-2) of the first tandem solar cell (10) is electrically insulated from the second absorber layer (12′-2) of the second tandem solar cell (10′).

11. The tandem solar cell module (1) according to claim 10, wherein the first electrodes (11-1, 11′-1) of the first and second tandem solar cells have been integrally formed (as a first electrode substrate) and separated by means of a mechanical scribing or a laser ablation process, whereby the first insulating cut (16) is produced, and wherein the second electrodes (12-1, 12′-1) of the first and second 3T tandem solar cells are formed integrally and separated by means of a mechanical scribing or laser ablation process, whereby the second insulating cut (17) is produced.

12. A method of manufacturing a tandem solar cell module (1) according to claim 8, comprising the following steps:
i) cutting a first electrode substrate to form the first electrodes (11-1, 11′-1) of the at least first and second tandem solar cells (10, 10′), thereby forming the first insulating cut (16) between the first electrodes (11-1, 11′-1);
ii) cutting a second electrode substrate to form the second electrodes (12-1, 12′-1) of the at least first and second tandem solar cells (10, 10′), thereby forming the second insulating cut (17) between the second electrodes (12-1, 12′-1);
iii) Producing the first absorber layer (11-2, 11′-2) of the at least first and second tandem solar cell (10, 10′) on the first electrodes (11-1, 11′-1) in one piece;
iv) producing the second absorber layer (12-2, 12′-2) of the at least first and second tandem solar cells (10, 10′) on the second electrodes (12-1, 12′-1) in one piece;
v) Creating the first transparent conductive layer (11-3, 11′-3) in one piece on the first absorber layer (11-2, 11′-2);
vi) Creating the second transparent conductive layer in one piece on the second absorber layer (12-2, 12′-2);
vii) cutting the one piece first absorber layer and the one piece first transparent conductive layer of the first and second 3T-tandem solar cells (10, 10′) by means of a mechanical scribing or a laser ablation process, so that the first absorber layers (11-2, 11′-2) and the first transparent conductive layers (11-3, 11′-3) of the first and second tandem solar cells (10, 10′) are produced in the form of the first solar cells (11, 11′);
viii) cutting the one piece second absorber layer and the one piece second transparent conductive layer of the first and second 3T-tandem solar cells (10, 10′) by means of a mechanical or a laser ablation process, so that the second absorber layers (12-2, 12′-2) and the second transparent conductive layers (12-3, 12′-3) of the first and second tandem solar cells (10, 10′) are produced in the form of the second solar cells (12, 12′);
ix) arranging and aligning the connecting layer (13, 13′), each comprising at least one one-piece conductive element and the embedding means (13-2), between the first and second solar cells (11, 11′, 12, 12′) so that the first and second solar cells (11, 11′, 12, 12′) are superimposed and so that the at least one one-piece conductive element forms a plurality of contact points (K1, K2, K3, K4, K5) with the first and second transparent conductive layers (11-3, 12-3), respectively;
x) heating the connecting layer (13) so that the embedding means (13-2) is adhesively bonded to the first and second solar cells (11, 11′, 12, 12′) and so that the at least one one-piece conductive element (13-3, 13′-3) forms a plurality of contact points (K1, K2, K3, K4, K5) with the first and second transparent conductive layers (11-3, 11′-3, 12-3, 12′-3) respectively.

13. The method according to claim 12, wherein the at least one one-piece conductive element (13-3, 13′-3) is connected to the third electrode (13-1, 13′-1) or forms it integrally, wherein upon heating the third electrode (13-1) of the first tandem solar cell (10) is electrically contacted with the first and/or the second electrode (11′-1, 12′-1) of the second tandem solar cell (10′).

14. The method according to claim 12, wherein the first and second insulating layers (14, 14′, 15, 15′) are produced after step viii).
